(19) United States
(12) Patent Application Publication
(10) Pub. No.: US 2002/0031914 A1
(43) Pub. Date: Mar. 14, 2002

(54) POST-PLASMA PROCESSING WAFER CLEANING METHOD AND SYSTEM

(76) Inventors: JULIA S. SVIRCHEVSKI, SAN JOSE, CA (US); KATRINA A. MIKHAYLICH, SAN JOSE, CA (US); JEFFREY J. FARBER, DELMAR, NY (US)

Correspondence Address: MARTINE & PENILLA, LLP, 710 LAKEWAY DRIVE, SUITE 170, SUNNYVALE, CA, 94085, US

(21) Appl. No.: 09/336,401

(22) Filed: Jun. 18, 1999

(51) Int. Cl. H01L 21/302; H01L 21/461

(52) U.S. Cl. 438/712

(57) ABSTRACT

A method and system are provided for cleaning a surface of a semiconductor wafer following a plasma etching operation. The method is preferably performed inside a brush box and involves wetting the surface of the semiconductor wafer by using a non-splash rinse technique. The non-splash rinse technique is configured to quickly and evenly saturate the surface of the semiconductor wafer with a liquid (preferably de-ionized water). The wetting will therefore remove unwanted residues that could otherwise further cause stains or scratches on the wafer surface. Following the wetting operation, the surface of the wafer may be finely scrubbed with a cleaning brush that applies a chemical solution to the surface of the wafer. A second cleaning brush may also be implemented so that both the top and the bottom surfaces of the wafer may be finely scrubbed.

### BACKGROUND OF THE INVENTION

1. Field of the Invention

The present invention relates to semiconductor wafer cleaning and, more particularly, to techniques for more carefully applying water to the surface of a semiconductor wafer after a plasma etching operation.

2. Description of the Related Art

In the semiconductor chip fabrication process, it is well-known that there is a need to clean a wafer where a fabrication operation has been performed that leaves unwanted residual material on the surface of the wafer. An example of such a fabrication operation is plasma etching (e.g., tungsten etch back (WEB)). If left on the surface of the wafer for subsequent fabrication operations, the unwanted residual material may induce, among other things, defects related to inappropriate interactions between residuals on the wafer and the environment. In some cases, such defects may cause devices on the wafer to become inoperable. In order to avoid the undue costs of discarding wafers having inoperable devices, it is necessary to clean the wafer adequately yet efficiently after fabrication operations that leave unwanted residue on the surface of the wafer.

FIG. 1A shows a high-level schematic diagram of a wafer cleaning system 50. The cleaning system 50 typically includes a load station 10 where a plurality of wafers in a cassette 14 may be inserted for cleaning through the system. Once the wafers are inserted into the load station 10, a wafer 12 may be taken from the cassette 14 and moved into a brush box one 16a, where the wafer 12 is scrubbed with selected chemicals and water (e.g., DI water). The wafer 12 is then moved to a brush box two 16b. After the wafer has been scrubbed in the brush boxes 16, the wafer is moved into a spin, rinse, and dry (SRD) station 20 where de-ionized water is sprayed onto the surface of the wafer and spun to dry. After the wafer has been placed through the SRD station 20, the wafer is moved to an unload station 22.

FIG. 1B shows a detailed view of a cleaning process performed in brush box one 16a. In the brush box one 16a, the wafer 12 is inserted between a top brush 30a and a bottom brush 30b. The wafer 12 is being rotated by rollers 18 and the brushes 30, thereby enabling the brushes 30 to adequately clean the top and bottom surfaces of the wafer 12. In certain circumstances, the bottom surface of the wafer is required to be cleaned as well because contaminants from the bottom may migrate to the top surface 12a. Although both the top surface 12a and the bottom surface of the wafer are scrubbed with the brushes 30, the top surface 12a that is scrubbed with the top brush 30a is the primary surface targeted for cleaning, since the top surface 12a is where the integrated circuit devices are being fabricated.

FIG. 1C shows a cross-sectional view of the wafer 12, where layers have been fabricated over a semiconductor substrate 100. In a typical fabrication process, an oxide layer 102 may be deposited over the semiconductor substrate 100. Next, well-known photolithography and etching techniques may be used to form patterned trenches 108 in the oxide layer 102. A titanium nitride (TiN) layer 104 may then be sputtered over the oxide layer 102, thereby covering the top surface of the oxide layer 102 and the patterned trenches 108. Following sputtering of TiN, a tungsten (W) layer 106 may be deposited over the TiN layer 104, thereby covering the TiN layer 104 and filling the patterned trenches 108. The TiN layer 104 typically serves as an adhesive and a barrier between the tungsten layer 106 and the oxide layer 102.

FIG. 1D shows the semiconductor wafer 12 of FIG. 1C, where a tungsten etch- back (WEB) operation has been performed to the top surface of the wafer 12. The tungsten layer 106 may be etched down such that the top surface of the wafer 12 is substantially flat and the TiN layer 106 is again exposed. The tungsten layer 106 within the patterned trenches 108 remains exposed to the top surface of the wafer. Unfortunately, the WEB operation is likely to leave unwanted residues over the surface of the wafer that may inappropriately react with water or other chemicals in subsequent cleaning operations.

FIG. 1E shows a top-down view of the whole wafer 12 of FIG. 1D, where unwanted stains have been formed on the top surface of the wafer 12 during the initial cleaning operations following the WEB operation. As stated above, after a typical WEB operation, the top surface may be coated with residues (e.g., containing TiₓF_{y}, and other polymers) that can subsequently cause unwanted reactions, as indicated by the simplified illustration of a stained surface 152 on the wafer 12. In tests, the size of the stains were measured to range between 1 and 50 microns.

By way of example, when the wafer 12 enters the cleaning system 50, the wafer 12 enters the cassette 14 and may be sprayed with water while in the cassette 14 in order to wet the surface. Alternatively, the wafer can be sprayed with an entrance spray of water as the wafer 12 enters brush box one 16a or brush box two 16b. Unfortunately, in such water spraying operations, the application of water tends to be non-uniform in that portions of the wafer may receive the application of water before other portions. The portions of the wafer that are sprayed initially will likely undergo unwanted reactions with the residues that were left on the wafer 12 after the WEB operation. Although the spraying operation may saturate the entire surface of wafer 12, the initial droplets that are applied to the wafer surface will necessarily cause the wafer to have portions of stained surface 152 and portions of non-stained surface 150. Furthermore, in addition to stains, the techniques of spraying water associate with splashing may cause defects that appear as micro-scratches on the surface of the wafer after brush scrubbing.

Unwanted stains or micro-scratches on the wafer surface may cause, among other things, inappropriate interactions between metallization features and yield loss. These interactions may destroy the operability of devices on the wafer. A portion of the wafer with stains or micro-scratches typically must be discarded, which will ultimately add substantial cost to the overall fabrication process. Unfortunately, the stains or micro-scratches on the surface generally cannot be removed in subsequent cleaning or fabrication operations.

In view of the foregoing, there is a need for a cleaning process that avoids the problems of the prior art by implementing techniques for avoiding unwanted chemical interactions after a plasma etching operation, such as WEB.

### SUMMARY OF THE INVENTION

Broadly speaking, the present invention fills these needs by providing a method and system for quickly and evenly rinsing the surface of a semiconductor wafer following plasma processing. It should be appreciated that the present invention can be implemented in numerous ways, including as a process, an apparatus, a system, a device or a method. Several inventive embodiments of the present invention are described below.

In one embodiment, a method is disclosed for cleaning a surface of a semiconductor wafer following a plasma etching operation. The method is preferably performed inside a brush box and involves wetting the surface of the semiconductor wafer by using a non-splash rinse technique. The non-splash rinse technique is configured to quickly and evenly saturate the surface of the semiconductor wafer with a liquid (preferably de-ionized water). Following the wetting operation, the surface of the wafer may be finely scrubbed with a cleaning brush that applies a chemical solution to the surface of the wafer. A second cleaning brush may also be implemented to finely scrub the bottom surface of the wafer.

In another embodiment, a system is disclosed for cleaning a semiconductor wafer after a fabrication operation. The system includes a brush box having at least one liquid outlet for applying a non-splash flow of a liquid over the top surface of the semiconductor wafer. The non-splash flow of the liquid is configured to evenly saturate substantially all of the top surface of the wafer. The wafer is preferably configured to sit over the bottom brush and rotate against rollers. Then, the top surface and the bottom surface of the wafer may be finely scrubbed with a top brush and a bottom brush, respectively. The system may also include a second brush box, where the non-splash rinse technique can also similarly be implemented in the second brush box.

In yet another embodiment, a method is disclosed for cleaning a surface of a semiconductor wafer following a plasma etching operation. The method includes wetting the surface of the semiconductor wafer with a liquid. The wetting is preferably performed by setting at least one delivery source over the rotating surface of the wafer in order to evenly saturate the surface of the wafer. The surface of the wafer is quickly saturated in less than about 4 seconds while minimizing splashing over the surface of the wafer.

Advantageously, the present invention provides methods and systems for applying liquid to the surface of a wafer by using a non-splash, even, and quick application technique. As a result, where a wafer has undergone a plasma etching operation, the applied liquid will not undergo unwanted reactions with residual chemicals on the wafer surface. In addition to substantially eliminating stains, the techniques of the present invention substantially reduces the number of micro-scratches that may be formed on the wafer surface during cleaning operations. The methods of the present invention are particularly beneficial in post tungsten etch-back (WEB) cleaning operations, whereby the wafers are rotated and rinsed with the non-splash technique before commencing normal brush box cleaning. If the non-splash rinsing is performed in a first brush box, the second brush box can be used for chemical scrubbing. The brushes of the second brush box can therefore remain filled with an optimal chemical concentration level, thus improving optimal cleaning repeatability. Ultimately, the methods and systems disclosed herein will substantially reduce undue costs in the overall fabrication process because the number of damaged wafers that must be discarded will be substantially reduced.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

The present invention will be readily understood by the following detailed description in conjunction with the accompanying drawings. To facilitate this description, like reference numerals designate like structural elements.

FIG. 1A shows a high-level schematic diagram of a wafer cleaning system.

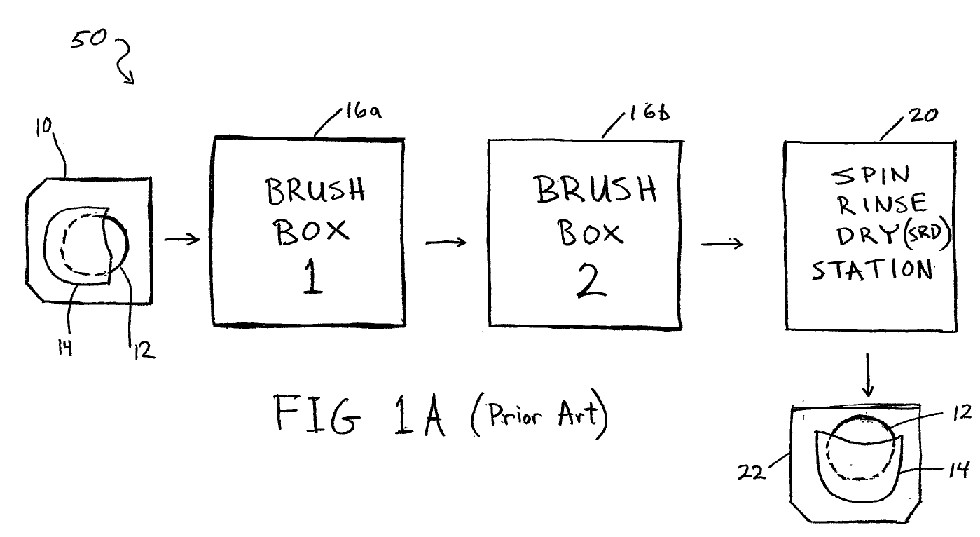

FIG. 1B shows a detailed view of a cleaning process performed in a brush box.

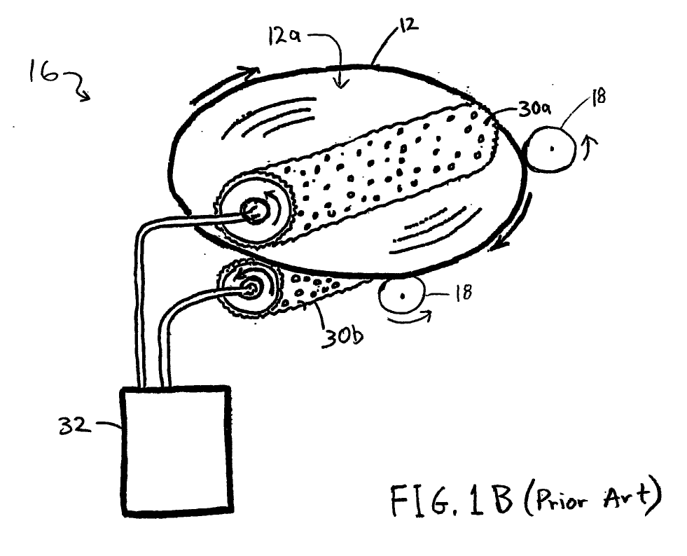

FIG. 1C shows a cross-sectional view of a wafer, where layers have been fabricated over a semiconductor substrate.

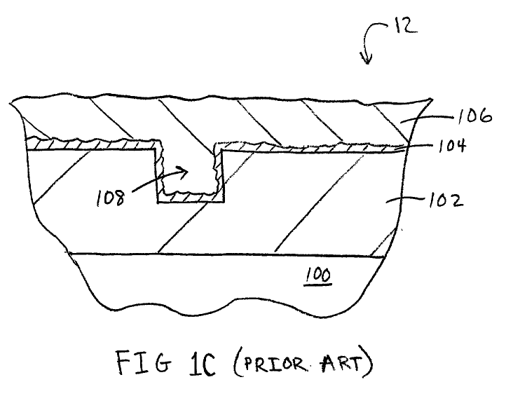

FIG. 1D shows the semiconductor wafer 12 of FIG. 1C, where a tungsten etch-back (WEB) operation has been performed to the top surface of the wafer 12.

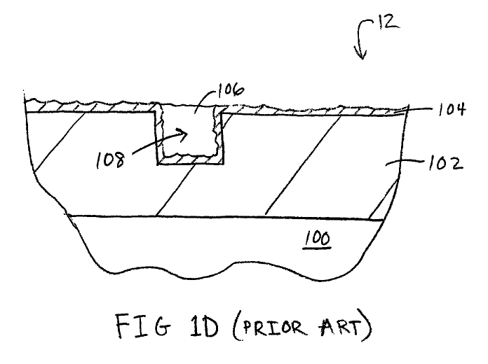

FIG. 1E shows a top-down view of the whole wafer 12 of FIG. 1D, where unwanted stains have been formed on the top surface of the wafer 12 during the initial cleaning operations following the WEB operation.

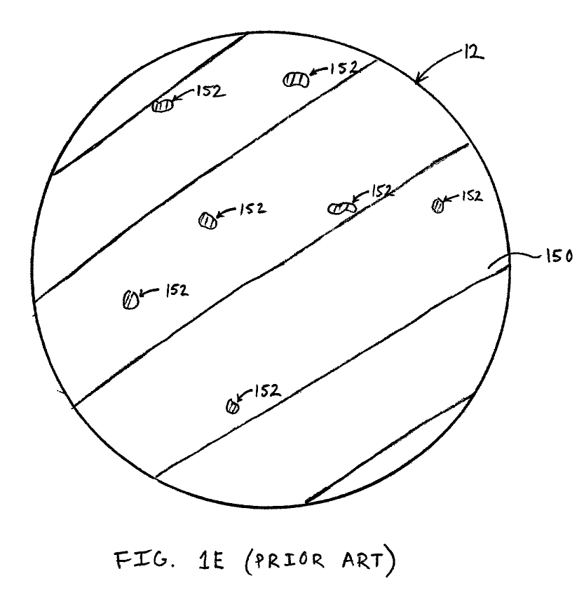

FIGS. 2A and 2B show a non-splash technique of applying liquid to the rotating top wafer surfaces by way of top liquid outlets, in accordance with one embodiment of the present invention.

FIGS. 2C and 2D show a non-splash technique of applying liquid to the wafer surfaces by way of top liquid outlets and bottom liquid outlets, in accordance with one embodiment of the present invention.

FIGS. 3A and 3B show a non-splash technique of applying liquid to the top wafer surface by way of top liquid outlets, the wafer being rotated by rollers, in accordance with one embodiment of the present invention.

FIGS. 3C and 3D show a non-splash technique of applying liquid to the wafer surfaces by way of top liquid outlets and bottom liquid outlets, the wafer being rotated by rollers, in accordance with one embodiment of the present invention.

FIG. 4 shows an enlarged view of a liquid outlet fixedly positioned over a wafer, in accordance with one embodiment of the present invention.

FIG. 5 shows a flow chart for a wafer cleaning process, in accordance with one embodiment of the present invention.

FIG. 6 shows a flow chart for an alternative wafer cleaning process, in accordance with one embodiment of the present invention.

### DETAILED DESCRIPTION OF THE PREFERRED EMBODIMENTS

An invention for methods and systems for carefully rinsing a surface of a semiconductor wafer after plasma processing and before brush scrubbing are disclosed. In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to unnecessarily obscure the present invention.

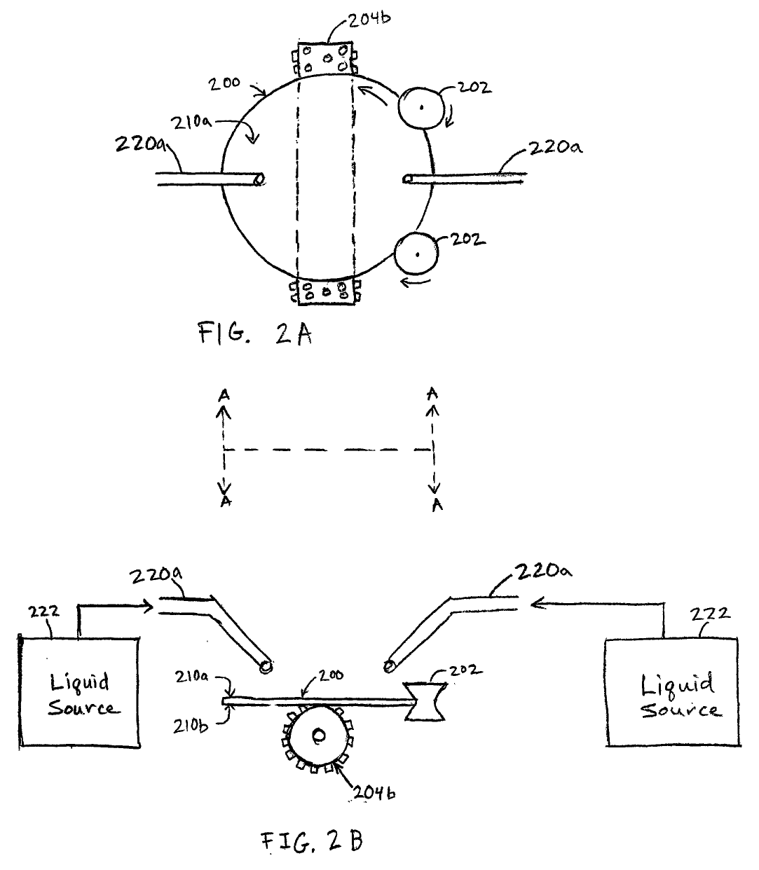

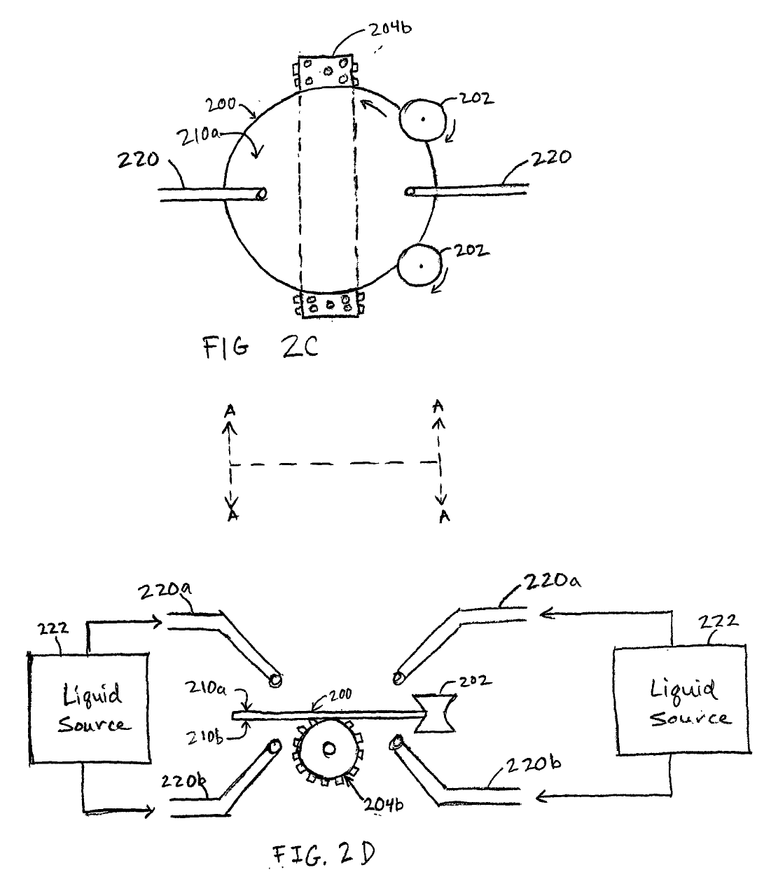

FIGS. 2A and 2B show a non-splash technique of applying liquid to the top wafer surfaces 210a by way of top liquid outlets 220a, in accordance with one embodiment of the present invention. The liquid is preferably water, and most preferably de-ionized water. The wafer 200 may be held by a bottom cleaning brush 204b and a set of rollers 202. Although FIG. 2A illustrates two rollers 202, it should be appreciated that additional or fewer rollers 202 can be used, preferably as long as the wafer is properly held on the bottom cleaning brush 204b. In this embodiment, a liquid source 222 is used to supply liquid through a conduit that leads to the liquid outlets 220.

The liquid outlets 220 may be configured to distribute liquid over the wafer surfaces 210 as the wafer rotates and is balanced on the bottom cleaning brush 204b and the two rollers 202. In a preferred embodiment, the liquid outlets 220 implement a technique that is designed to saturate the wafer surface 210 in a non-splash, even, and quick manner. As used herein, “saturate the wafer surface” preferably means to cover substantially all of the wafer surface 210 with liquid. “Non-splash” preferably means that the liquid exits the liquid outlets 220 and saturates the wafer surface 210 with substantially no splashing. “Even” preferably means that the liquid is distributed over the wafer surface 210 at a substantially constant flow rate. “Quick” preferably means that for an 8-inch wafer, the wafer surface 210 is saturated in about 4 seconds or less.

Assuming the diameter of the wafer 200 is about 8 inches, it is preferred that the wafer 200 rotates between about 2 revolutions per minute and about 20 revolutions per minute, and most preferably about 5 revolutions per minute. The liquid from the liquid outlet 220 preferably exits the liquid outlet 220 at a rate of between about 50 ml/minute and 300 ml/minute, and most preferably about 150 ml/minute. Regardless of any predetermined parameters, however, it is preferred that the non-splash, even, and quick technique of distributing the liquid be maintained throughout the liquid distribution operation.

As shown in FIG. 2B, two top liquid outlets 220a may be used to saturate the wafer surface 210a. In other embodiments of the present invention, additional or fewer liquid outlets may be used, preferably as long as the liquid outlets are positioned in such a way as to saturate at least the top wafer surface 210a in a non-splash, even, and quick manner.

FIGS. 2C and 2D show a non-splash technique of applying liquid to the wafer surfaces 210 by way of top liquid outlets 220a and bottom liquid outlets 220b, in accordance with one embodiment of the present invention. As shown in FIG. 2D, two top liquid outlets 220a may be used for applying liquid to the top surface 210a, while two bottom liquid outlets 220b may be used for applying liquid to the bottom surface 210b. Such an embodiment includes a total of four liquid outlets 220, as shown in FIG. 2D. In an alternative embodiment (not shown), two liquid outlets may be used for applying liquid to the top surface, while one liquid outlet may be used for applying liquid to the bottom surface. In other embodiments of the present invention, additional or fewer liquid outlets 220 may be used, preferably as long as the liquid outlets 220 are positioned in such a way as to saturate at least the top wafer surface 210a in a non-splash, even, and quick manner.

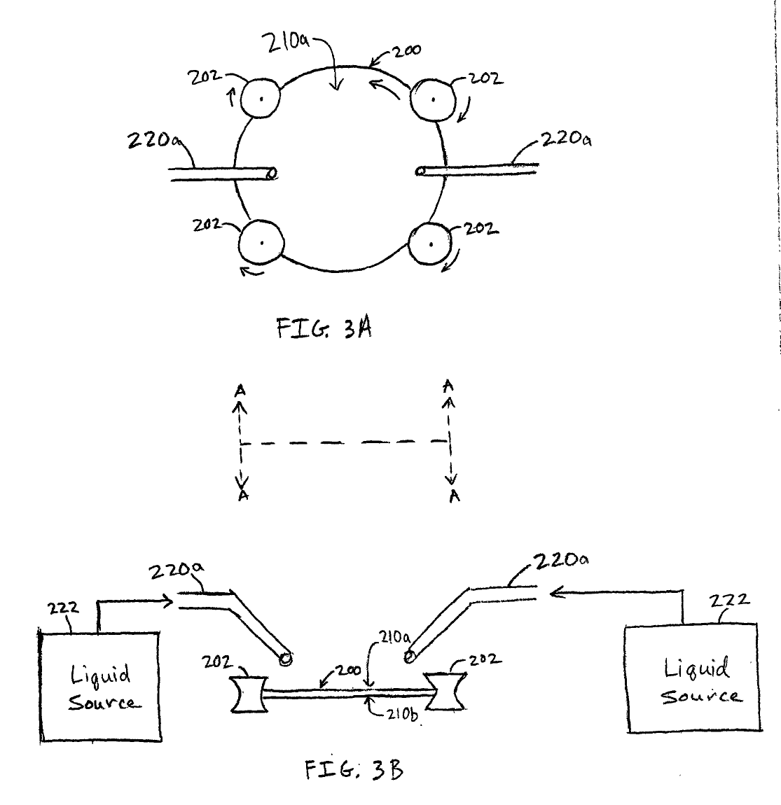

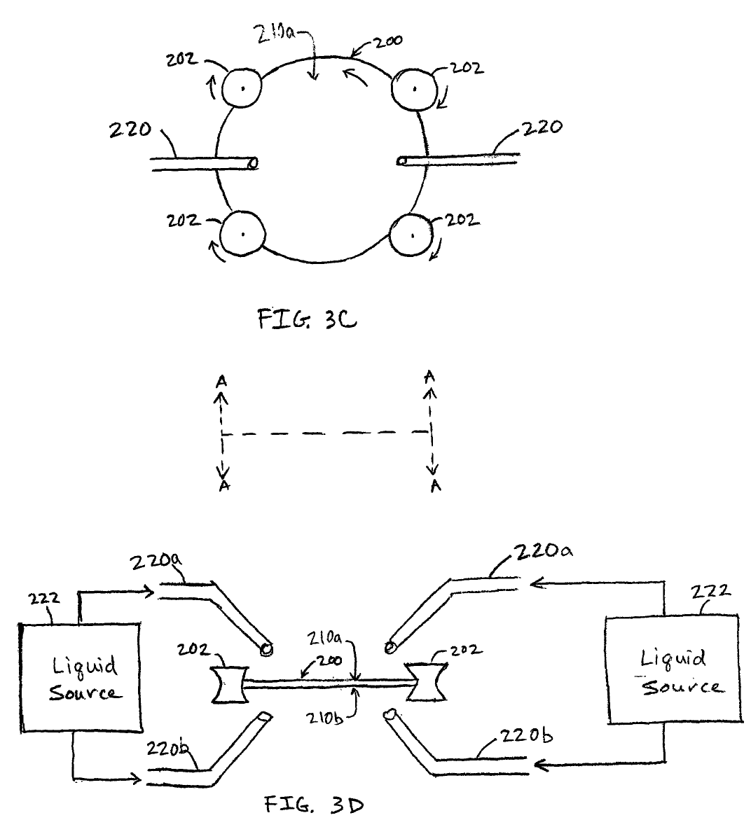

FIGS. 3A and 3B show a non-splash technique of applying liquid to the top wafer surfaces 210a by way of top liquid outlets 220a, the wafer being rotated by rollers 202, in accordance with one embodiment of the present invention. It is preferred that cleaning brushes 204 do not touch the wafer surface 210. The wafer may be held by a set of rollers 202. Although FIG. 3A illustrates four rollers 202, it should be appreciated that additional or fewer rollers 202 can be used, preferably as long as the wafer is properly held between the rollers 202. In this embodiment, a liquid source 222 is used to supply liquid through a conduit that leads to the liquid outlets 220.

The liquid outlets 220 may be configured to distribute liquid over the wafer surfaces 210 as the wafer rotates between the rollers 202. In a preferred embodiment, the liquid outlets 220 implement a technique that is designed to saturate the wafer surface 210 in a non-splash, even, and quick manner.

As shown in FIG. 3B, two top liquid outlets 220a may be used to saturate the wafer surface 210a. In other embodiments of the present invention, additional or fewer liquid outlets may be used, preferably as long as the liquid outlets are positioned in such a way as to saturate at least the top wafer surface 210a in a non-splash, even, and quick manner.

FIGS. 3C and 3D show a non-splash technique of applying liquid to the wafer surfaces 210 by way of top liquid outlets 220a and bottom liquid outlets 220b, the wafer being rotated by rollers 202, in accordance with one embodiment of the present invention. As shown in FIG. 3C, two top liquid outlets 220a may be used for applying liquid to the top surface 210a, while two bottom liquid outlets 220b may be used for applying liquid to the bottom surface 210b. Such an embodiment includes a total of four liquid outlets, as shown in FIG. 3D. In an alternative embodiment (not shown), two liquid outlets may be used for applying liquid to the top surface, while one liquid outlet may be used for applying liquid to the bottom surface. In other embodiments of the present invention, additional or fewer liquid outlets may be used, preferably as long as the liquid outlet are positioned in such a way as to saturate at least the top wafer surface 210a in a non-splash, even, and quick manner.

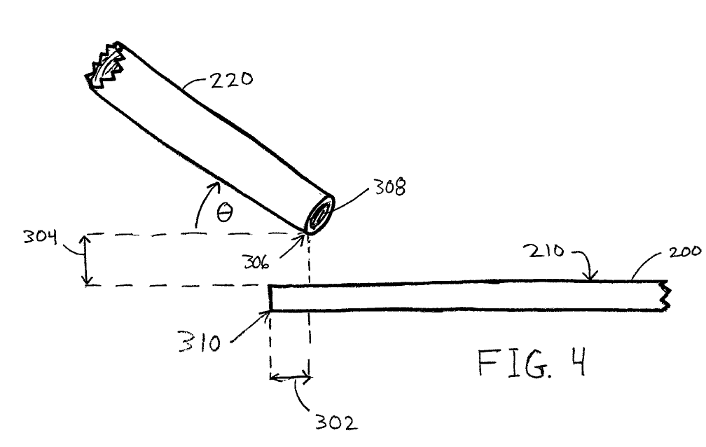

FIG. 4 shows an enlarged view of one of the liquid outlets 220 fixedly positioned over the wafer 200, in accordance with one embodiment of the present invention. Although FIG. 4 shows one of the top liquid outlets 220a, it should be apparent that the following discussion is applicable to any one of the bottom liquid outlets 220b as well.

In a preferred embodiment, the position of the liquid outlet 220 relative to the wafer 200 may be defined by at least three parameters. First, the liquid outlet 220 may be positioned relative to the wafer surface 210 such that the plane of the wafer surface 210 and the radial axis of the liquid outlet 220 form an angle θ. Second, the liquid outlet 220 may be positioned such that outer side 306 of the liquid outlet opening 308 is inward from the wafer edge 310 a predetermined edge distance 302. Third, the liquid outlet 220 may be positioned such that the outer side 306 of the liquid outlet opening 308 is above the wafer surface 210 a predetermined raised distance 304.

The angle θ is preferably between about 5 degrees and about 35 degrees, and most preferably about 15 degrees. The edge distance 302 is preferably between about 2 mm and about 30 mm, and most preferably about 5 mm. The raised distance 304 is preferably between about 2 and about 15 mm, and most preferably about 7 mm.

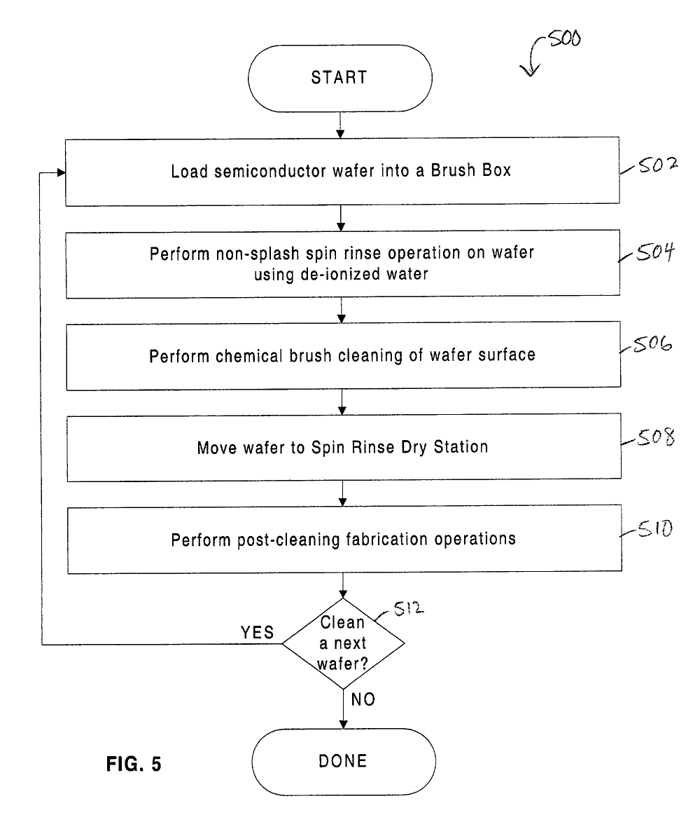

FIG. 5 shows a flow chart for a wafer cleaning process 500, according to one embodiment of the present invention. The process starts in operation 502 where a semiconductor wafer is loaded into a brush box from a wafer cassette. At this point, the method moves to an operation 504 where the surface of the wafer is wet using a non-splash, quick and even application of liquid (as discussed above with reference to FIGS. 2 and 3).

The wetting operation of the present invention eliminates the need for a brush box entrance spray, which was discussed above with reference to the related art. The wetting operation also eliminates the need for a spin, rinse, and dry (SRD) station prior to the wafer entering the brush box, also discussed above with reference to the related art. Furthermore, the wetting operation preferably occurs after the wafer is completely inside the brush box. By ensuring the wafer is completely inside the brush box, other wafers that are still in the loading cassette can be protected from liquid that may splash back onto these other wafers from the wetting operation. As discussed above with reference to the related art, inappropriate splashing on a wafer may cause wafer defects, such as stains and micro-scratches on the wafer surface.

Returning to the discussion of FIG. 5, after operation 504, the process moves to operation 506 where a chemical brush cleaning may be performed on the wafer surface. After the chemical brush cleaning, the process proceeds to operation 508 where the wafer is moved to a spin, rinse, and dry (SRD) station. The process then moves to operation 510 where post-cleaning fabrication operations are performed on the wafer.

The process then goes on to a decision operation 512 where it is determined whether another wafer is to be cleaned. If there is no next wafer to be cleaned, the process is done. On the other hand, if another wafer is to be cleaned, the process goes back to operation 502 where a semiconductor wafer is loaded into the brush box. The foregoing process 500 continues until it is determined that there is no next wafer in decision operation 512.

In the process 500, the cleaning process was optimized such that the non-splash rinse and the chemical cleaning were preformed in one brush box. However, in other embodiments, the brush box can be one of a set of brush boxes and the chemical cleaning and other rinse operations can be performed in adjacent brush boxes and stations.

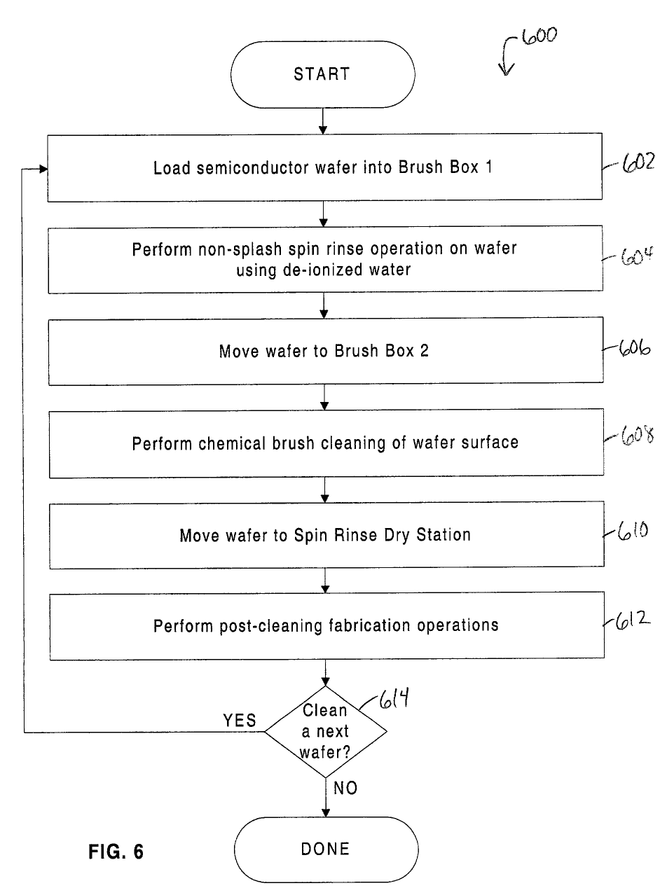

FIG. 6 shows a flow chart for an alternative wafer cleaning process 600, according to one embodiment of the present invention. In this embodiment, the non-splash rinse is performed in one brush box, and then any chemical cleaning or additional rinsing may be performed in an adjacent brush box. The process starts in operation 602 where a semiconductor wafer is loaded into Brush Box 1. The process then moves to operation 604 where a non-splash spin rinse operation is performed on the wafer using de-ionized water, as discussed above with reference to FIGS. 2 and 3.

Next, the process moves to operation 606 where the wafer is moved to Brush Box 2. Alternatively, instead of moving immediately to Brush Box 2, a chemical brush cleaning operation or related operations may be performed on the wafer in Brush Box 1 before the wafer is moved to Brush Box 2. Once in Brush Box 2, the process moves to operation 608 where a chemical brush cleaning is performed on the wafer surface. The process then goes on to operation 610 where the wafer is moved to an SRD station. The process now moves to operation 612 where post-cleaning fabrication operations are performed on the wafer.

The process then goes on to a decision operation 614 where it is determined whether another wafer is to be cleaned. If there is no next wafer to be cleaned, the process is done. On the other hand, if another wafer is to be cleaned, the process goes back to operation 602 where a semiconductor wafer is loaded into the Brush Box 1. The foregoing process 600 continues until it is determined that there is no next wafer in decision operation 614.

It is important to note that once the wafer is rinsed using the non-splash rinse technique, any subsequent contact with water or chemicals will no longer cause the unwanted staining or damage discussed with reference to the prior art.

While this invention has been described in terms of several preferred embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as falling within the true spirit and scope of the invention.

What is claimed is:

1. A method of cleaning a surface of a semiconductor wafer following a plasma etching operation, comprising:
wetting the surface of the semiconductor wafer by using a non-splash rinse technique, the non-splash rinse technique being configured to quickly and evenly saturate the surface of the semiconductor wafer.

2. A method of cleaning a surface of a semiconductor wafer following a plasma etching operation as recited in claim 1, further comprising: keeping the semiconductor wafer substantially dry after the plasma etching operation and before the wetting operation of the semiconductor wafer.

3. A method of cleaning a surface of a semiconductor wafer following a plasma etching operation as recited in claim 1, further comprising:
scrubbing the surface of the wafer with a cleaning brush that applies a chemical solution to the surface of the wafer after the wetting.

4. A method of cleaning a surface of a semiconductor wafer following a plasma etching operation as recited in claim 3, wherein the wetting and the scrubbing are performed in a brush box, the brush box having the cleaning brush and a second cleaning brush, the second cleaning brush being implemented to scrub a bottom surface of the wafer.

5. A method of cleaning a surface of a semiconductor wafer following a plasma etching operation as recited in claim 3, wherein the wetting is performed in a brush box and the scrubbing is performed in a second brush box, the second brush box having the cleaning brush and a second cleaning brush, the second cleaning brush being implemented to scrub a bottom surface of the wafer.

6. A method of cleaning a surface of a semiconductor wafer following a plasma etching operation as recited in claim 1, wherein the wetting of the surface of the semiconductor wafer further comprises:
setting a first delivery source and a second delivery source over the surface of the wafer in order to wet the surface of the wafer at a predetermined flow rate of water; and
setting the predetermined flow rate to be between about 50 ml/minute and about 300 ml/minute.

7. A method of cleaning a surface of a semiconductor wafer following a plasma etching operation as recited in claim 6, wherein the wetting of the surface of the semiconductor wafer further comprises:
setting a time of less than about 4 seconds to wet substantially all of a top surface of the wafer.

8. A method of cleaning a surface of a semiconductor wafer following a plasma etching operation as recited in claim 1, further comprising:
rotating the wafer about a radial axis at a rate of between about 2 revolutions per minute and about 20 revolutions per minute.

9. A method of cleaning a surface of a semiconductor wafer following a plasma etching operation as recited in claim 1, wherein the semiconductor wafer is completely inside a brush box, and no other wafer than the semiconductor wafer that is inside the brush box is exposed to liquid by the wetting.

10. A method of cleaning a surface of a semiconductor wafer following a plasma etching operation as recited in claim 1, wherein the wetting occurs inside a brush box, and the brush box has no entrance spray.

11. A method of cleaning a surface of a semiconductor wafer following a plasma etching operation as recited in claim 1, wherein the wetting occurs inside a brush box, and a spin, rinse, and dry (SRD) operation is not performed on the semiconductor wafer after the plasma etching operation and before the wetting.

12. A system for cleaning a semiconductor wafer after a fabrication operation, comprising:
a brush box, the brush box including:
at least one liquid outlet for applying a non-splash flow of a liquid over the top surface of the semiconductor wafer, the non-splash flow of the liquid being configured to evenly saturate substantially all of a top surface of the wafer.

13. A system for cleaning a semiconductor wafer after a fabrication operation as recited in claim 12, wherein the liquid is selected from the group consisting of water and de-ionized water.

14. A system for cleaning a semiconductor wafer after a fabrication operation as recited in claim 12, wherein the brush box further comprises:
a top brush and a bottom brush for scrubbing a top surface and a bottom surface of the semiconductor wafer, the semiconductor wafer being configured to sit over the bottom brush and rotate against rollers.

15. A system for cleaning a wafer after a plasma etching operation as recited in claim 12, further comprising:
a second brush box, the second brush box including:
a top brush and a bottom brush for scrubbing a top surface and a bottom surface of the semiconductor wafer, the semiconductor wafer being configured to sit over the bottom brush and rotate against rollers.

16. A system for cleaning a semiconductor wafer after a plasma etching operation as recited in claim 14, wherein the top brush and the bottom brush used for scrubbing the top surface and the bottom surface of the semiconductor wafer implement a chemical brush cleaning solution.

17. A system for cleaning a semiconductor wafer after a fabrication operation as recited in claim 12, wherein the at least one top water outlet is arranged relative to the top surface of the semiconductor wafer at an angle, and is raised above the top surface at a raised distance, and overlies an edge of the top surface at an overlying distance.

18. A system for cleaning a semiconductor wafer after a fabrication operation as recited in claim 17, wherein the angle ranges between about 5 degrees and about 35 degrees.

19. A system for cleaning a semiconductor wafer after a fabrication operation as recited in claim 17, wherein the raised distance is at least 5 mm.

20. A system for cleaning a semiconductor wafer after a fabrication operation as recited in claim 17, wherein the overlying distance is between about 3 mm and about 20 mm.

21. A method of cleaning a surface of a semiconductor wafer following a plasma etching operation, comprising:
wetting the surface of the semiconductor wafer, the wetting being performed by setting at least one delivery source over the surface of the wafer in order to evenly saturate the surface of the wafer;
the surface of the wafer being quickly saturated in less than about 4 seconds while minimizing splashing over the surface of the wafer.

22. A method of cleaning a surface of a semiconductor wafer following a plasma etching operation as recited in claim 21, further comprising:
setting an outlet end of the at least one delivery source to at least partially overlie an edge of the wafer.

23. A method of cleaning a surface of a semiconductor wafer following a plasma etching operation as recited in claim 21, further comprising:
setting the outlet of the at least one delivery source at an angle relative to the surface of the wafer to range between about 5 degrees and about 35 degrees. 24. A method of cleaning a surface of a semiconductor wafer following a plasma etching operation as recited in claim 21, wherein the plasma etching operation is a tungsten etch-back (WEB) operation.
